(19) United States
(12) Patent Application Publication
(10) Pub. No.: US 2008/0136407 A1
(43) Pub. Date: Jun. 12, 2008

(54) SYSTEM AND METHOD FOR MAGNETIC FIELD EXPOSURE INDICATION

(75) Inventors: Paul A. Moskowitz, Yorktown Heights, NY (US); Clifford A. Pickover, Yorktown Heights, NY (US)

Correspondence Address: CANTOR COLBURN LLP - IBM RESEARCH TRIANGLE PARK, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/567,427

(22) Filed: Dec. 6, 2006

(51) Int. Cl. G01R 33/00

(52) U.S. Cl. 324/226

(57) ABSTRACT

Systems and methods for magnetic field exposure indication. Exemplary embodiments include a magnetic field exposure indication system, including a main carrier body, a magnetic storage medium disposed on the main carrier body, an magnetochromic material indicator associated with the magnetic storage medium to indicate that the medium has been exposed to an a magnetic disruption, wherein the magnetochromic indicator is positioned on the main carrier body adjacent the magnetic storage medium where magnetic field disruption can be oriented to the magnetic storage medium and a comparison area disposed on the main carrier body, the comparison area including sample color regions illustrating the beginning color of an unexposed material and a color of the magnetochromic material indicator having been exposed to a magnetic disruption sufficient to damage the magnetic storage medium. Alternate exemplary embodiments include a magnetic disruption source to erase data stored on the magnetic storage medium.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to magnetic storage media, and more particularly to systems and methods for magnetic field exposure indication.

2. Description of Background

Storage media containing sensitive, confidential, personal, or private information are proliferating rapidly. One example is the use of magnetic strips on credit cards, debit cards, etc., to hold personal information: e.g., the credit card number, expiration date, name of cardholder. Such magnetic stripe storage areas on the credit card may be easily damaged, if not erased, by exposure to commonly encountered magnetic fields.

Coercivity is the magnetic field needed to change data bits in the media. The coercivity of a common credit card is about 300 Oersteds (Oe), which is considered low coercivity (nicknamed “LoCo”). Consequently, magnetic money clips, refrigerator magnets, etc., can damage the data on a credit card's stripe. Magnetic field disruption can damage a single bit, or erase or make the data unreadable. In the case of credit cards, disruption of a single bit by an unwanted magnetic field may make the card totally unreadable.

Besides the danger from household magnetics, magnetic anti-theft devices attached to retain items or library books are either de-activated or re-activated through the use of alternating magnetic fields; metal detectors used at airports also produce alternating magnetic fields. Various metal detectors may disrupt storage media as that on credit cards. Though normally used at levels below that of credit card damage, defective units risk damage to credit cards or other magnetic storage media.

Other storage media include audio tape, video tape, computer tape, flexible disk storage (floppies) and computer hard disk drives, certain kinds of smart cards, ID cards, passports, badges, key cards, etc., which permit entry to places of work, hotel rooms, cruise ship rooms, etc. Other types of magnetic media such as Ferroelectric Random Access Memory, FRAM, may also be changed by exposure to a magnetic field.

Currently, there is a need for detection of damaging magnetic fields so that owners of magnetic media can take precautions to protect the magnetic media. Furthermore, there is a need for detection of magnetic fields that are strong enough to erase magnetic storage media so that a user who wants to erase storage media prior to disposal can know that a sufficient magnetic field has been attained.

### BRIEF SUMMARY

Embodiments of the invention include a credit card, including a main body having a front surface and a rear surface, a magnetic storage stripe disposed on the rear surface of the main body, a first magnetochromic material indicator, or other magnetic indicator material, disposed on the front surface and associated with the magnetic storage stripe to indicate that the magnetic storage stripe has been exposed to a magnetic field disruption, wherein the magnetochromic material indicator is positioned on the main body where the magnetic field disruption can be oriented to the magnetic storage stripe, a second magnetochromic material indicator disposed on the rear surface adjacent to the magnetic storage stripe to indicate that the magnetic storage stripe has been exposed to an a magnetic disruption, wherein the magnetochromic material indicator is positioned on the main body adjacent the magnetic storage stripe where magnetic field disruption can be oriented to the magnetic storage medium, a first comparison area disposed on the front surface, the first comparison area including sample color regions illustrating the beginning color of an unexposed magnetochromic material and a color of the magnetochromic material indicator having been exposed to a magnetic disruption sufficient to damage the magnetic storage stripe, a second comparison area disposed on the rear surface, the second comparison area including sample color regions illustrating the beginning color of an unexposed magnetochromic material and a color of the magnetochromic material indicator having been exposed to a magnetic disruption sufficient to damage the magnetic storage stripe, legible letters disposed adjacent at least one of the first and second magnetochromic material indicators, the legible letters becoming obscured when exposed to the magnetic field disruption and letters disposed adjacent at least one of the first and second magnetochromic material indicator, the letters becoming legible when exposed to the magnetic field disruption. Adjacent may mean near, or close to, or in the vicinity where the disruption magnetic field may influence both the magnetic indicator material and the magnetic storage medium. Color change may include changes in color, color intensity, or gray scale.

Additional embodiments include a magnetic field exposure indication system, including a main carrier body, a magnetic storage medium disposed on the main carrier body, an magnetochromic material indicator associated with the magnetic storage medium to indicate that the medium has been exposed to an a magnetic disruption, wherein the magnetochromic indicator is positioned on the main carrier body adjacent the magnetic storage medium where magnetic field disruption can be oriented to the magnetic storage medium and a comparison area disposed on the main carrier body, the comparison area including sample color regions illustrating the beginning color of an unexposed material and a color of the magnetochromic material indicator having been exposed to a magnetic disruption sufficient to damage the magnetic storage medium.

Further embodiments include a magnetic field exposure indication system, including a main carrier body, a magnetic storage medium disposed on the main carrier body, a magnetochromic material indicator associated with the magnetic storage medium to indicate that the medium has been exposed to an a magnetic disruption sufficient to erase data stored on the magnetic storage medium, wherein the magnetochromic indicator is positioned on the main carrier body adjacent the magnetic storage medium where magnetic field disruption can be oriented to the magnetic storage medium, a comparison area disposed on the main carrier body, the comparison area including sample color regions illustrating the beginning color of an unexposed material and a color of the magnetochromic material indicator having been exposed to a magnetic disruption sufficient to alter data stored on the magnetic storage medium and a magnetic disruption source for providing a magnetic field disruption to the magnetic storage medium through the use of a magnetic field to erase data stored on the magnetic storage medium.

Other systems, methods, and/or computer program products according to embodiments will be or become apparent to one with skill in the art upon review of the following drawings and detailed description. It is intended that all such additional systems, methods, and/or computer program products be included within this description, be within the scope of the present invention, and be protected by the accompanying claims.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a front view of an exemplary system for magnetic field exposure indication; and

FIG. 2 illustrates rear view of an exemplary system for magnetic field exposure indication.

The detailed description explains the preferred embodiments of the invention, together with advantages and features, by way of example with reference to the drawings.

### DETAILED DESCRIPTION

Exemplary embodiments include systems and methods that provide a magnetic field indicator, e.g. a magnetochromic material or other magnetic indicating material, which can be affixed to storage media so that disruption of the media via a magnetic field is clearly and automatically visually indicated at the time of a magnetic field disruption. As such, the systems and methods indicate that a magnetic storage medium may have been compromised by exposure to a magnetic field. In exemplary implementations, visual indication can be provided when a credit card, a hard drive or other storage medium has been exposed to an unwanted field that might compromise the integrity of the data. For example, a visual indicator on the credit card can show that the magnetic storage media has been exposed to a magnetic field.

In alternate exemplary embodiments, an indication showing that a storage medium device has been successfully erased (e.g. intentionally erased) through the application of a magnetic field is also provided. Disruption by magnetic field is an effective and easy means for erasing the information stored on media, however, the user may not be aware if the field strength was sufficiently high or where best to apply the field. In addition, the user may not recall which storage media were disrupted, especially when considering several devices in a room over a period of time. As such, the systems and methods provide a visual indication that the hard drive or other media is “safe” to discard. In an exemplary implementation, if a device can no longer be turned on, such as could be the case with an inoperable PC, the storage unit can still contain sensitive information that can be recovered by some intruder using various means. Therefore, the systems and methods can provide an indication that the media has received enough magnetic disruption to discard the device with confidence.

Magnetochromic materials, such as Li_{0.9}Mo₆O₁₇, which exhibit a persistent color-change are well known. For example, a plastic sheet can be prepared with a magnetochromic material such that a green plastic sheet changes color, becoming black, when penetrated by a magnetic field perpendicular to its surface. Therefore, the use of magnetochromic materials is useful for viewing magnetic poles, fields, and transitions. Color change may occur at a low field strength (10 to 50 gauss), and remain after the field is removed.

In exemplary embodiments in which a user desires to protect storage media, an exemplary system can include a storage medium, and an automatic, persistent, color indicator on the magnetic storage medium to indicate a magnetic disruption. The storage medium may be any of: hard disk drive, credit card, magnetic tape, video tape, audio tape, flash memory, other memory or storage in computers, cameras, consumer items, smart cards, phones, ID cards, badges, diskette, disk drive, etc. The indicator may be a magnetochromic material affixed to storage medium. A magnetic indicator may be disposed on the main carrier body of the storage medium. A carrier body may include the case, cover, chassis, or observable surface of a computing device, such as a personal computer (PC) or any handheld computing device. The carrier body may include the case, cover, or mounting structures of a hard disk drive (HDD) or any of the HDD structural elements including platters, sliders, actuator arm, actuator, and spindle. The carrier body may include a surface of a credit card, badge or other identity document.

The material may be positioned at strategic areas of the storage medium in order to guide users as to most efficacious regions to which the media can be subject to a magnetic field. The user of this system includes PC users, companies, services, IT shops, employers, disposal agencies, device users, etc.

In exemplary embodiments in which a user desires to erase and discard storage media, an exemplary system can include a storage medium, a magnetic disruption source, and an automatic, persistent, and color indicator on the magnetic storage medium to indicate a magnetic disruption. The storage medium may be any of: hard disk drive, credit card, magnetic tape, video tape, audio tape, flash memory, other memory or storage in computers, cameras, consumer items, smart cards, phones, ID cards, badges, diskette, disk drive, etc. The disruption may be done through the use of a magnetic field (e.g. a strong magnet). The indicator may be a magnetochromic material affixed to storage medium. The material may be positioned at strategic areas of the storage medium in order to guide users as to most efficacious regions for subjecting the media to a magnetic field. The user of this system includes PC users, companies, services, IT shops, employers, disposal agencies, device users, etc.

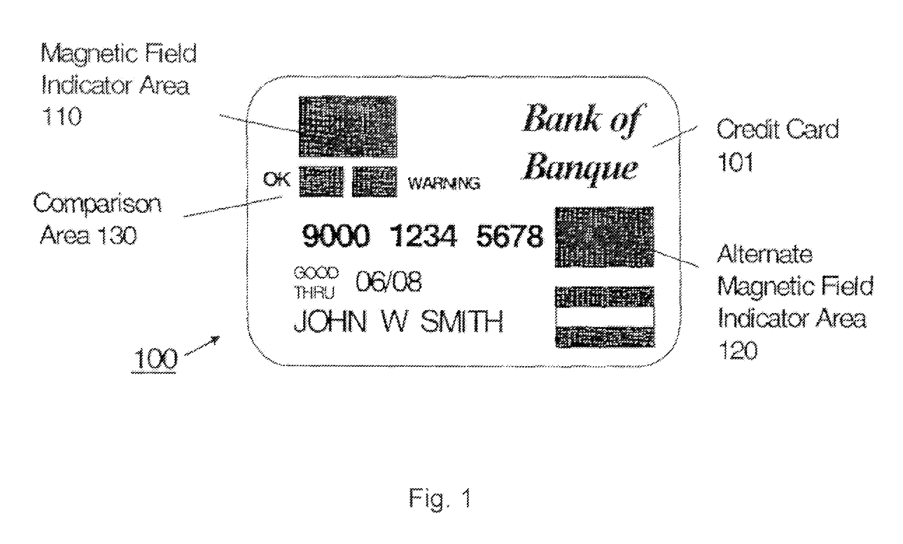

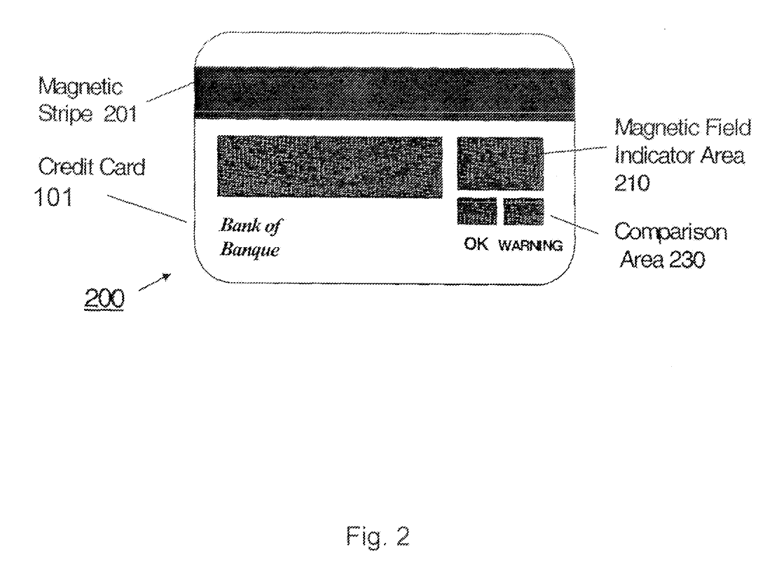

FIG. 1 illustrates a front view of an exemplary system 100 for magnetic field exposure indication. System 100 includes a credit card 101 that has a magnetically sensitive material 110 placed in visually observable location on surface of credit card 101. The magnetically sensitive material may be of one color but may change color when exposed to a magnetic field. The credit card 101 may be equipped with a comparison area 130 in which sample color regions are shown for purposes of illustrating the beginning color of an unexposed material or a color of the changed material indicating a warning. Alternatively, legible letters may be placed in the indicator area, e.g., “OK”, and “WARNING”. These letters may become obscured when the material is exposed to a magnetic field. Additionally, words may become visible when the material is exposed to a magnetic field. For example, “OK” can persist in safe fields, and disappear in unsafe fields, while “WARNING” can disappear in safe fields and appear in unsafe fields. The magnetically sensitive material 110 may be placed in an unused area of the credit card 101 or may be place in alternate locations 120, such as adjacent the numeric indicia are on the front of the credit card 101. The material 110 may also be placed strategically next to or over the magnetic strip (or either side of the card, see for example FIG. 2 below) to provide a targeted indication that the magnetic strip has been erased, or an attempt has been made to alter (e.g. reprogram) the stripe. In an exemplary implementation, the magnetically (e.g., magnetochromic) sensitive material 110 is applied to the card “after” the credit card manufacturer has initially written the strip. In this way, the magnetically sensitive material 110 could then be used to show tampering, e.g. to show that the magnetic stripe has been exposed to a field great enough to re-write the data contained on the stripe.

FIG. 2 illustrates rear view of an exemplary system 200 for magnetic field exposure indication. System 200 is the reverse side of the credit card 101 of FIG. 1, which has a magnetically sensitive material 210 placed in visually observable locations. The magnetically sensitive material 210 may be of one color but may change color when exposed to a magnetic field. The credit card 101 may be equipped with a comparison area 230 in which sample color regions are shown for purposes of illustrating the beginning color of an unexpressed material or a color of the changed material indicating a warning. Alternatively, legible letters may be placed in the indicator area, e.g., “OK”, and “WARNING”. These letters may become obscured when the material is exposed to a magnetic field. Additionally, words may become visible when the material is exposed to a magnetic field. For example, “OK” can persist in safe fields, and disappear in unsafe fields, while “WARNING” can disappear in safe fields and appear in unsafe fields. If the magnetic stripe on the reverse of the credit card is exposed to a field of sufficient strength to disrupt or change a bit, the magnetically sensitive material 210 in the indicator area provides the visual indication of a magnetic disruption. Alternatively, invisible letters are placed in the indicator area that may become legible when exposed to a magnetic field. In addition of more than one material is used, each of which is sensitive to a different level of magnetic field, then the indicator would show the level of field exposure as different areas changed their optical appearance.

In an alternative embodiment, the magnetic indicating material is placed on the surface of a storage material, such as a hard drive (or on a computer case near a hard drive) to show that the storage medium may have been exposed to a disruptive magnetic field.

In another exemplary embodiment, a method includes presenting a main carrier body; a magnetic storage medium disposed on the main carrier body; a magnetic material indicator associated with the magnetic storage medium to indicate that the medium has been exposed to an a magnetic disruption, wherein the magnetic indicator is positioned on the main carrier body adjacent the magnetic storage medium where magnetic field disruption can be oriented to the magnetic storage medium and in addition providing a magnetic disruption source for providing a magnetic field disruption to the magnetic storage medium through the use of a magnetic field to erase data stored on the magnetic storage medium. Further, the magnetic storage medium may include at least one of hard disk drive, credit card, magnetic tape, driver's license, ID card, entry card, video tape, audio tape, flash memory, FRAM memory, other memory or storage in computers, cameras, consumer items, smart cards, phones, ID cards, badges, diskette, passport, and zip drive. The magnetic material indicator may be magnetochromic.

This invention provides value to many different possible classes of users: (1) The end user who derives value knowing that their card is possibly unusable or has been altered—and the user may have a sense as to when or why this alteration may have occurred; (2) A place of business that derives value knowing that a card may be unusable at a point of sale or a point of validation (e.g. use of card to enter a building or to provide identification). The card may also indicate that the stripe has been re-written after manufacture. The magnetochromic material may also be applied to the edge of the card—or over (or near) a person's photo in a card that has a photo.

Driver's Licenses—Over 40 states currently use the magnetic strip or 2D bar code technology to encode data on state-issued drivers' licenses. This information may be quite sensitive and may be used by many agencies in the future. Privacy concerns abound. Data that is currently stored on some state's drivers' licenses include, but is not limited to: name; address; second address; date of birth; height; weight; sex; eye color; hair color; social security number; organ donor information; medical indicators; alias name, address, date of birth or social security number; electronic image of signature; electronic photo image (KY); digital fingerprints (DC, GA, HI); facial recognition template (TN), etc.

Data integrity is crucial. The police may use this when a person is pulled over for speeding on the interstate. The data on the license can be instantly cross-referenced with other databases to find out if there are any outstanding warrants, violations, etc. Businesses are also using driver's license scanning equipment. The first businesses to start swiping are bars and e convenience stores. They are doing this in the name of age verification and fraud detection, but misuse is possible. Businesses many times do not ask consent from their customers—or even bother to notify them—before swiping a card. In most states it is legal to scan licenses and upload the data to a customer database for future analysis and use.

Other places installing license-scanning equipment are airports, hospitals, federal buildings, etc. Other uses for the systems and methods described herein include but are not limited to: immigration cards, anti-terrorism use, social security, passports, etc.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

What is claimed is:

1. A credit card, comprising:
a main body having a front surface and a rear surface;
a magnetic storage stripe disposed on at least one of the front surface and the rear surface of the main body;
a magnetic material indicator disposed on at least one of the front surface and the rear surface of the main body, the magnetic material indicator being associated with the magnetic storage stripe to indicate that the magnetic storage stripe has been exposed to a magnetic field disruption; and
a comparison area disposed on at least one of the front surface and the rear surface, the comparison area including sample color regions illustrating the beginning color of an unexposed magnetic material indicator and a color of the magnetic material indicator having been exposed to the magnetic field disruption sufficient to damage the magnetic storage stripe.

2. The system of claim 1 further comprising legible letters disposed adjacent said magnetic material indicator, the legible letters becoming obscured when exposed to the magnetic field disruption.

3. The system of claim 1 further comprising letters disposed adjacent said magnetic material indicator, the letters becoming legible when exposed to the magnetic field disruption.

4. The system as claimed in claim 1 wherein the magnetic material indicator is magnetochromic.

5. The system as claimed in claim 4 wherein the magnetic material indicator is Li_{0.9}Mo₆O₁₇.

6. The system as claimed in claim 1 in which the magnetic material indicator provides an indication of an attempt to rewrite or alter the information on the magnetic storage stripe.

7. A magnetic field exposure indication system, comprising:
a main carrier body;
a magnetic storage medium disposed on the main carrier body; and
a magnetic material indicator associated with the magnetic storage medium to indicate that the medium has been exposed to a magnetic field disruption, and positioned on the main carrier body proximate the magnetic storage medium where the magnetic field disruption can be oriented to the magnetic storage medium.

8. The system of claim 7 further comprising a comparison area disposed on the main carrier body, the comparison area including a sample indicating region illustrating the beginning indication of an unexposed material and an indicating region of the magnetic material indicator having been exposed to the magnetic disruption sufficient to damage the magnetic storage medium.

9. The system as claimed in claim 7 wherein the magnetic storage medium includes at least one of hard disk drive, credit card, magnetic tape, driver's license, ID card, entry card, video tape, audio tape, flash memory, FRAM memory, other memory or storage in computers, cameras, consumer items, smart cards, phones, ID cards, badges, diskette, passport, and zip drive.

10. The system as claimed in claim 7 further wherein the magnetic material indicator is a plurality of magnetic indicators associated with the magnetic storage medium, the plurality of indicators indicating different ranges of magnetic field disruption exposure.

11. The system as claimed in claim 10 further comprising legible letters disposed adjacent the magnetic material indicator, the legible letters becoming obscured when exposed to the magnetic field disruption.

12. The system as claimed in claim 10 further comprising letters disposed adjacent the magnetic material indicator, the letters becoming legible when exposed to the magnetic field disruption.

13. The system as claimed in claim 7 wherein the magnetic material indicator is magnetochromic.

14. The system of claim 13 further comprising a comparison area disposed on the main carrier body, the comparison area including sample color regions illustrating the beginning color of an unexposed material and a color of the magnetochromic material indicator having been exposed to the magnetic disruption sufficient to damage the magnetic storage medium.

15. The system of claim 7 further comprising a magnetic disruption source for providing the magnetic field disruption to the magnetic storage medium through the use of a magnetic field to erase data stored on the magnetic storage medium.

16. The system as claimed in claim 15 wherein a magnetic material indicator is disposed on the main carrier body adjacent the magnetic storage medium where the magnetic disruption source can be oriented to guide users as to most efficacious regions for subjecting the magnetic storage medium to a magnetic field to erase the data on the magnetic storage medium.

17. The system as claim in claim 7 in which the magnetic material indicator provides an indication of an attempt to rewrite or alter the information on the magnetic storage medium.

18. A method comprising:
providing a main carrier body, a magnetic storage medium disposed on the main carrier body, a magnetic material indicator associated with the magnetic storage medium to indicate that the medium has been exposed to an a magnetic disruption, wherein the magnetic indicator is positioned on the main carrier body proximate the magnetic storage medium where a magnetic field disruption can be oriented to the magnetic storage medium;
providing a magnetic disruption source for providing the magnetic field disruption to the magnetic storage medium through the use of the magnetic field disruption to erase data stored on the magnetic storage medium; and
obtaining an indication from the magnetic material indicator, the indication being indicative that the magnetic field disruption is sufficient to erase the data stored on the magnetic storage medium.

19. The method of claim 18 wherein the magnetic storage medium includes at least one of hard disk drive, credit card, magnetic tape, driver's license, ID card, entry card, video tape, audio tape, flash memory, FRAM memory, other memory or storage in computers, cameras, consumer items, smart cards, phones, ID cards, badges, diskette, passport, and zip drive.

20. The method of claim 18 wherein the magnetic material indicator is magnetochromic and the indication is a color change to the magnetic material indicator.
